(19) United States
(12) Patent Application Publication
(10) Pub. No.: US 2010/0123245 A1
(43) Pub. Date: May 20, 2010

(54) Semiconductor integrated circuit devices and display apparatus including the same

(75) Inventors: Tae-Jung Lee, Yongin-si (KR); Kee-In Bang, Cheongwon--gun (KR); Myoung-Kyu Park, Yongin-si (KR); Kyoung-Eun Uhm, Incheon (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 12/591,110

(22) Filed: Nov. 9, 2009

(30) Foreign Application Priority Data
Nov. 17, 2008 (KR) 10-2008-0114153

(51) Int. Cl. H01L 23/48

(52) U.S. Cl. 257/737; 257/E23.021

(57) ABSTRACT

A semiconductor integrated circuit device includes: an electrostatic discharge (ESD) impurity region formed in a substrate; a bump formed on the substrate; and a first wiring layer and a second wiring layer formed at the same level under the bump. The first and second wiring layers are separated from each other, and at least part of each of the first and second wiring layers are overlapped by the bump. The first wiring layer is electrically connected to the ESD impurity region and the bump, and the second wiring layer is insulated from the bump.

### CROSS-REFERENCE TO RELATED APPLICATION(S)

This application claims priority under 35 U.S.C. §119 to Korean Patent Application No. 10-2008-0114153 filed on Nov. 17, 2008 in the Korean Intellectual Property Office, the disclosure of which is incorporated herein by reference in its entirety.

### BACKGROUND

1. Field

Example embodiments relate to semiconductor integrated circuit devices and display apparatus including the same.

2. Description of the Related Art

A conventional semiconductor integrated circuit device includes a plurality of bumps for inputting/outputting external signals. Each bump is connected to an external input/output terminal to exchange electrical signals. In addition, a pad is formed under each bump and connected to the internal circuit of the semiconductor integrated circuit device.

As semiconductor integrated circuit devices become smaller, the area of a semiconductor chip occupied by bumps increases. Therefore, a method of more efficiently utilizing space in semiconductor integrated circuit devices, which become more integrated and smaller, may be beneficial.

In addition, the operation of a conventional semiconductor integrated circuit device depends on whether each bump contacts an external input/output terminal normally. Thus, the contact stability of each bump and the external input/output terminal should be secured.

### SUMMARY

Example embodiments provide semiconductor integrated circuit devices having increased integration density. Example embodiments also provide display apparatus including semiconductor integrated circuit devices having increased integration density.

Example embodiments, however, are not restricted or limited to those set forth herein. The above and other example embodiments will become more apparent to one of ordinary skill in the art by referencing the detailed description provided below.

According to at least one example embodiment, a semiconductor integrated circuit device includes: an electrostatic discharge (ESD) impurity region formed in a substrate; a bump formed on the substrate; and a first wiring layer and a second wiring layer formed at the same or substantially the same level under the bump. The first and second wiring layers are separated from each other, and at least part of each of the first and second wiring layers is overlapped by the bump. The first wiring layer is electrically connected to the ESD impurity region and the bump, and the second wiring layer is insulated from the bump.

According to at least some example embodiments, the first wiring layer is arranged closer to the ESD impurity region than the second wiring layer. The bump has a long axis and a short axis, and the first wiring layer and the second wiring layer are separated from each other in a direction of the long axis of the bump. Each edge of each of the first wiring layer and the second wiring layer extends beyond the bump, excluding an edge of the first wiring layer and an edge of the second wiring layer, which are adjacent to each other. The first wiring layer is separated from the second wiring layer by a gap of less than or equal to about 4 μm.

According to at least some example embodiments, the semiconductor integrated circuit device further includes a third wiring layer extending from the ESD impurity region and electrically connecting the ESD impurity region to the first wiring layer. A plurality of second wiring layers are formed and separated from each other. A plurality of bumps extend in a first direction, and the second wiring layer extends in the first direction such that at least part of the second wiring layer is overlapped by the bumps.

According to at least some example embodiments, a semiconductor integrated circuit device further includes a second bump and a third bump, which are separated from the first bump. The first bump, the second bump, and the third bump are sequentially arranged in a second direction, and the third bump is formed adjacent to the ESD impurity region. Still further, the semiconductor integrated circuit further includes a third wiring layer and a fourth wiring layer formed respectively under the second bump and the third bump. The third and fourth wiring layers are overlapped by the second bump and the third bump, respectively. The third wiring layer is electrically connected to the ESD impurity region and the second bump, and the fourth wiring layer is electrically connected to the ESD impurity region and the third bump. Each edge of each of the third wiring layer and the fourth wiring layer extends beyond one of the second bump and the third bump.

A semiconductor integrated circuit device according to at least some example embodiments further includes a plurality of bump groups. Each of the plurality of bump groups includes a plurality of first bumps, a plurality of second bumps, or a plurality of third bumps separated from each other in a first direction.

At least one other example embodiment provides a semiconductor integrated circuit device including: an ESD impurity region extending in a first direction within a substrate; a first bump group including a plurality of first bumps arranged in the first direction on the substrate; a plurality of first pads formed respectively under the plurality of the first bumps; and a first wiring layer formed at the same or substantially the same level as the plurality of first pads. At least part of each of the plurality of first pads is overlapped by a corresponding one of the plurality of first bumps, and each of the plurality of first pads is electrically connected to the ESD impurity region and the corresponding one of the plurality of first bumps. The first wiring layer is separated from the plurality of first pads in a second direction, and extends in the first direction such that part of the first wiring layer is overlapped by the plurality of first bumps.

According to at least some example embodiments, the substrate has a long axis and a short axis. The first direction is a direction of the long axis of the substrate, and the second direction is a direction of the short axis of the substrate. The circuit device further includes at least one second bump group. Each of the at least one second bump groups includes a plurality of second bumps arranged on the substrate in the first direction. The at least one second bump groups and the first bump group are sequentially arranged in the second direction and are separated from each other.

According to at least some example embodiments, the substrate may be divided into a first region including a long edge of the substrate and a second region including the other long edge of the substrate. The ESD impurity region, the first bump group, the at least one second bump groups, the first pads, and the first wiring layer are formed in the first region, and symmetric versions of the ESD impurity region, the first bump group, the at least one second bump groups, the first pads, and the first wiring layer formed in the first region are formed in the second region. The at least one second bumps include a plurality of second bumps, and the circuit device further includes: a plurality of second pads formed respectively under the plurality of second bumps. Each of the plurality of second pads is overlapped by a corresponding one of the plurality of second bumps, and is electrically connected to the ESD impurity region and the corresponding one of the plurality of second bumps.

Each edge of each of the plurality of second pads extends beyond the corresponding one of the plurality of second bumps. Three edges of each of the first pads and the first wiring layer extend beyond the corresponding one of the plurality of first bumps, excluding an edge of each of the plurality of first pads and an edge of the first wiring layer, which are adjacent to each other. The plurality of first pads are separated from the first wiring layer by a gap of less than or equal to about 4 μm. The plurality of first pads are closer to the ESD impurity region than the first wiring layer, and the circuit device further includes a plurality of second wiring layers extending in the second direction to electrically connect each of the plurality of first pads to the ESD impurity region.

At least one other example embodiment provides a semiconductor integrated circuit device including: a bump formed on a substrate; and a first wiring layer and a second wiring layer formed at the same or substantially the same level under the bump. The first and second wiring layers are separated from each other by a gap of less than or equal to about 4 μm. At least part of each of the first and second wiring layers is overlapped by the bump.

According to at least one other example embodiment, a liquid crystal display includes a semiconductor integrated circuit device. According to at least this example embodiment, the semiconductor integrated circuit device includes: an electrostatic discharge (ESD) impurity region formed in a substrate; a bump formed on the substrate; and a first wiring layer and a second wiring layer formed at the same or substantially the same level under the bump. The first and second wiring layers are separated from each other, and at least part of each of the first and second wiring layers is overlapped by the bump. The first wiring layer is electrically connected to the ESD impurity region and the bump, and the second wiring layer is insulated from the bump.

According to at least one other example embodiment, a liquid crystal display includes a semiconductor integrated circuit device. According to at least this example embodiment, the semiconductor integrated circuit device includes: an ESD impurity region extending in a first direction within a substrate; a first bump group including a plurality of first bumps arranged in the first direction on the substrate; a plurality of first pads formed respectively under the plurality of first bumps; and a first wiring layer formed at the same or substantially the same level as the plurality of first pads. At least part of each of the plurality of first pads is overlapped by a corresponding one of the plurality of first bumps, and each of the plurality of first pads is electrically connected to the ESD impurity region and the corresponding one of the plurality of first bumps. The first wiring layer is separated from the plurality of first pads in a second direction, and extends in the first direction such that part of the first wiring layer is overlapped by the plurality of first bumps.

According to yet another at least one example embodiment, a liquid crystal display includes a semiconductor integrated circuit device. According to least this example embodiment, the semiconductor integrated circuit device includes: a bump formed on a substrate; and a first wiring layer and a second wiring layer formed at the same or substantially the same level under the bump. The first and second wiring layers are separated from each other by a gap of less than or equal to about 4 μm, and at least part of each of the first and second wiring layers is overlapped by the bump.

### BRIEF DESCRIPTION OF THE DRAWINGS

Example embodiments will become more apparent by describing in detail the attached drawings, in which:

FIGS. 1A through 2B are diagrams illustrating electrostatic discharge elements of a semiconductor integrated circuit device according to an example embodiment;

FIG. 3 is a layout view of a semiconductor integrated circuit device according to an example embodiment;

FIG. 4 is a cross-sectional view of the semiconductor integrated circuit device taken along the lines A-A′ and B-B′ of FIG. 1;

FIGS. 5A through 5C are enlarged views of regions C, D, and E shown in FIG. 3;

FIG. 6 is an enlarged view of a region F shown in FIG. 4;

FIG. 7 is a diagram illustrating a semiconductor integrated circuit device according to another example embodiment;

FIG. 8 is a partial perspective view of a liquid crystal panel assembly included in a liquid crystal display according to an example embodiment;

FIG. 9 is a partial top view of the liquid crystal panel assembly included in the liquid crystal display according to the example embodiment shown in FIG. 8; and

FIG. 10 is a graph illustrating an example dimple size with respect to a gap between wiring layers.

### DETAILED DESCRIPTION

Example embodiments will be understood more readily by reference to the following detailed description and the accompanying drawings. The example embodiments may, however, be embodied in many different forms and should not be construed as being limited to those set forth herein. Rather, these example embodiments are provided so that this disclosure will be thorough and complete. The present invention should be defined by the appended claims. In at least some example embodiments, well-known device structures and well-known technologies will not be specifically described in order to avoid ambiguous interpretation.

It will be understood that when an element is referred to as being “connected to” or “coupled to” another element, it can be directly on, connected or coupled to the other element or intervening elements may be present. In contrast, when an element is referred to as being “directly connected to” or “directly coupled to” another element, there are no intervening elements present. Like numbers refer to like elements throughout. As used herein, the term “and/or” includes any and all combinations of one or more of the associated listed items.

It will be understood that, although the terms first, second, third, etc., may be used herein to describe various elements, components and/or sections, these elements, components and/or sections should not be limited by these terms. These terms are only used to distinguish one element, component or section from another element, component or section. Thus, a first element, component or section discussed below could be termed a second element, component or section without departing from the teachings of the present invention.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated components, steps, operations, and/or elements, but do not preclude the presence or addition of one or more other components, steps, operations, elements, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Spatially relative terms, such as “below”, “beneath”, “lower”, “above”, “upper”, and the like, may be used herein for ease of description to describe the relationship of one element or feature to another element(s) or feature(s) as illustrated in the figures. It will be understood that the spatially relative terms are intended to encompass different orientations of the device in use or operation, in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

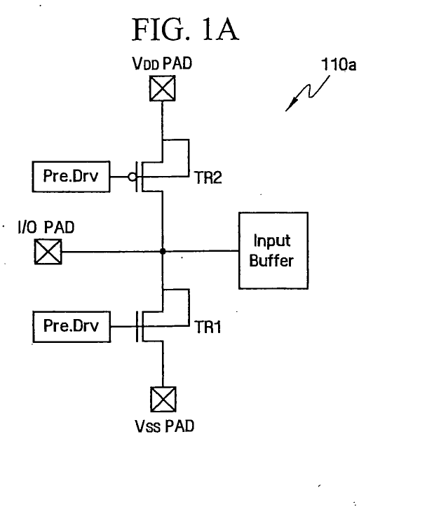

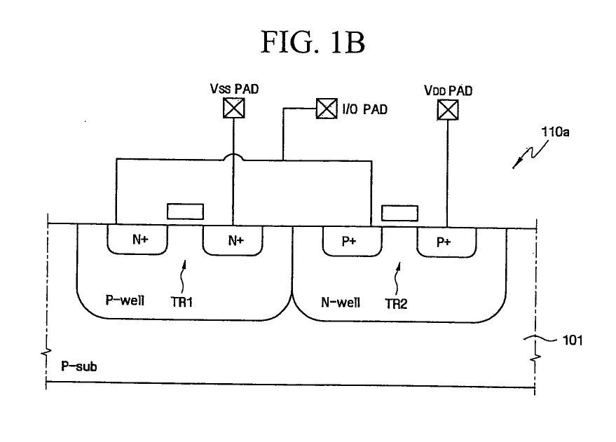

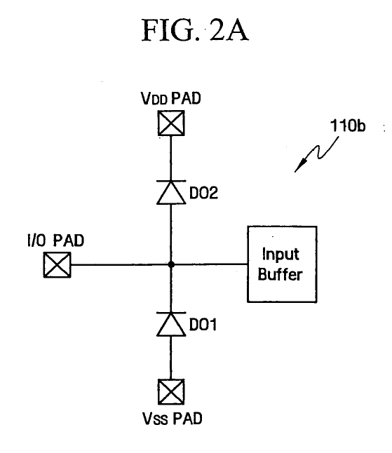

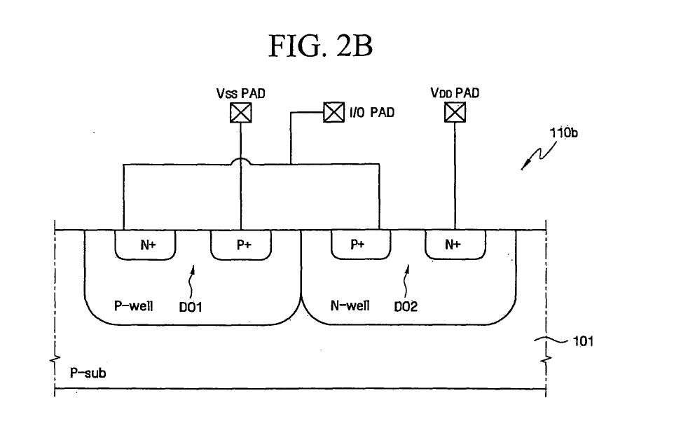

A semiconductor integrated circuit device according to at least one example embodiment includes electrostatic discharge (ESD) elements. The ESD elements included in the semiconductor integrated circuit device will now be described with reference to FIGS. 1A through 2B.

FIGS. 1A through 2B are diagrams illustrating ESD elements (or circuits) of a semiconductor integrated circuit device according to example embodiments. More specifically, FIG. 1A is a circuit diagram of a transistor ESD element 110a of a semiconductor integrated circuit device according to an example embodiment. FIG. 1B is a cross-sectional view of the transistor ESD element 110a shown in FIG. 1A.

FIG. 2A is a circuit diagram of a diode ESD element 110b of a semiconductor integrated circuit device according to an example embodiment. FIG. 2B is a cross-sectional view of the diode ESD element 110b shown in FIG. 2A.

According to at least one example embodiment, a semiconductor integrated circuit device may include one or more of the ESD protection elements 110a and 110b. The ESD protection element 110a or 110b is an element that protects the internal circuit of the semiconductor integrated circuit device from electrostatic charges. For example, the ESD protection element 110a or 110b absorbs (e.g., quickly absorbs) and discharges a relatively large amount of charge, which is instantaneously supplied from an external source, without affecting the internal circuit. The ESD protection element 110a or 110b may be designed based on a diode structure or a transistor structure.

As shown in FIGS. 1A and 1B, the ESD protection element 110a is electrically connected to an input/output pad 110 PAD in a semiconductor element so as to exchange electrical signals with an external device. The ESD protection element 110a included in the semiconductor integrated circuit device has a transistor structure.

When in a normal mode of operation, the transistor ESD protection element 110a applies a power supply voltage or a ground voltage to the input/output pad I/O PAD in response to a pre-driver signal Pre.Drv. When an electrostatic discharge occurs, the ESD protection element 110a allows a relatively large amount of electric current to flow, thereby protecting the semiconductor integrated circuit against stress caused by the electrostatic discharge. For example, the transistor ESD protection element 110a discharges a negative ESD voltage applied to the input/output pad I/O PAD to a ground voltage pad V_{SS} PAD and discharges a positive ESD voltage applied to the input/output pad I/O PAD to a power supply voltage pad V_{DD} PAD.

Still referring to FIGS. 1A and 1B, the transistor ESD protection element 110a includes at least two transistors. The at least two transistors include an n-channel metal-oxide semiconductor (NMOS) transistor TR1 and a p-channel metal-oxide semiconductor (PMOS) transistor TR2.

The source of the NMOS transistor TR1 is connected to the ground voltage V_{SS} PAD, whereas the drain of the NMOS transistor TR1 is connected to the input/output pad I/O PAD. The gate of the NMOS transistor TR1 is controlled by the pre-driver signal Pre.Drv. In this example, the source and drain of the NMOS transistor TR1 are a pair of N+-type impurity regions separated from each other in a P well. In example operation, the NMOS transistor TR1 discharges a negative ESD voltage applied to the input/output pad I/O PAD to the ground voltage pad V_{SS} PAD, thereby protecting the semiconductor integrated circuit.

Still referring to FIG. 1A, the source of the PMOS transistor TR2 is connected to the power supply voltage pad V_{DD} PAD, whereas the drain of the PMOS transistor TR2 is connected to the input/output pad I/O PAD. The gate of the PMOS transistor TR2 is controlled by the pre-driver signal Pre.Drv. In this example, the source and drain of the PMOS transistor TR2 are a pair of P+-type impurity regions separated from each other in an N well. In example operation, the PMOS transistor TR2 discharges a positive ESD voltage applied to the input/output pad I/O PAD to the power supply voltage pad V_{DD} PAD, thereby protecting the semiconductor integrated circuit.

Referring to FIGS. 2A and 2B, the ESD protection element 110b included in the semiconductor integrated circuit device has a diode structure.

The diode ESD protection device 110b includes a first diode DO1 connected between the input/output pad I/O PAD and a ground voltage pad V_{SS} PAD and a second diode DO2 connected between the input/output pad I/O PAD and a power supply voltage pad V_{DD} PAD.

The first diode DO1 includes an N+-type impurity region and a P+-type impurity region. The N+-type impurity region is connected to the input/output pad I/O PAD. The P+-type impurity region is separated from the N+-type impurity region, and connected to the ground voltage pad V_{SS} PAD.

The second diode DO2 includes a P+-type impurity region and an N+-type impurity region. The P+-type impurity region is connected to the input/output pad I/O PAD. The N+-type impurity region is separated from the P+-type impurity region and connected to the power supply voltage pad V_{DD} PAD.

When in a steady state, the first and second diodes DO1 and DO2 of the diode ESD protection element 110b remain turned off When static electricity occurs, the first and second diodes DO1 and DO2 are turned on to discharge the static electricity. In this case, the first and second diodes DO1 and DO2 discharge a relatively high voltage or a relatively large amount of charge, applied (e.g., instantaneously applied) to the input/output pad I/O PAD, to the power supply voltage pad V_{DD} PAD or the ground voltage pad V_{SS} PAD, with little or no affect to the internal circuit.

The ESD protection elements 110a and 110b illustrated in FIGS. 1A through 2B are mere examples, but semiconductor integrated circuit devices according to example embodiments may also include ESD protection elements other than the ESD protection elements 110a and 110b illustrated in FIGS. 1A through 2B. For example, semiconductor integrated circuit devices according to example embodiments may include all or substantially all types of ESD protection elements generally used in the field of semiconductor technology.

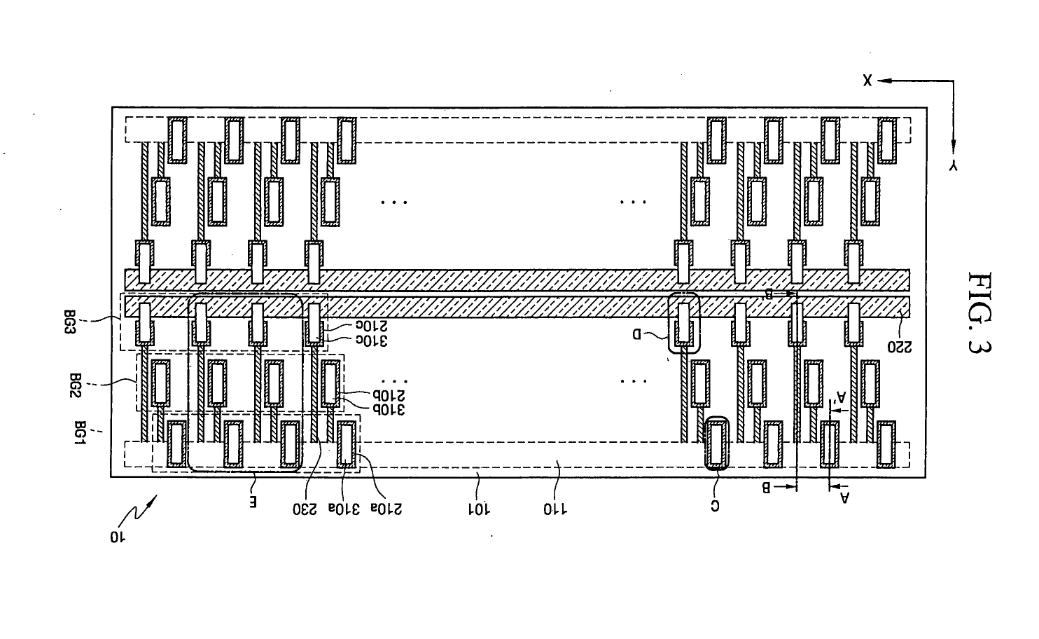

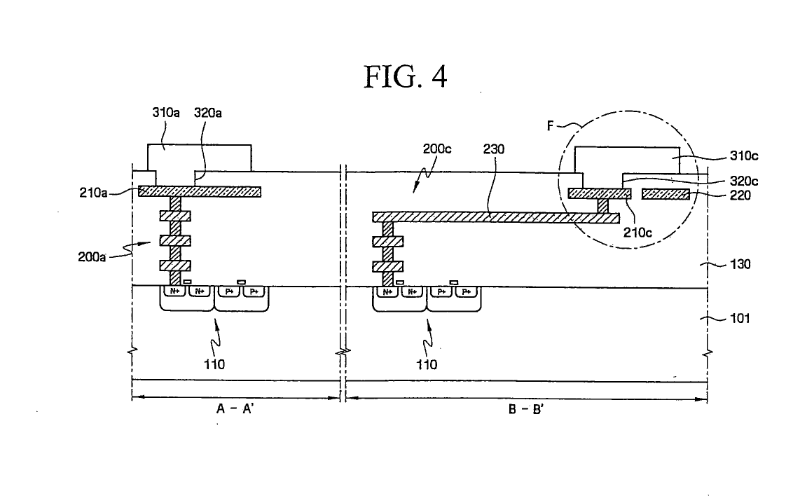

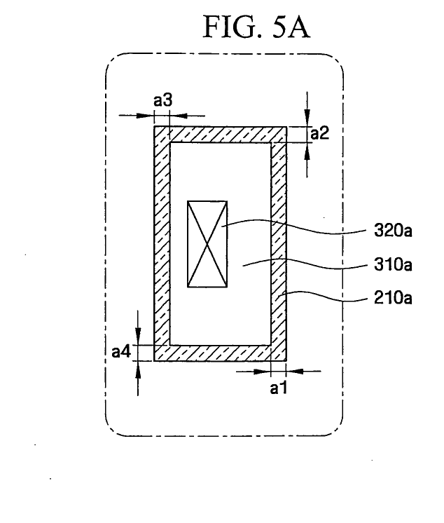

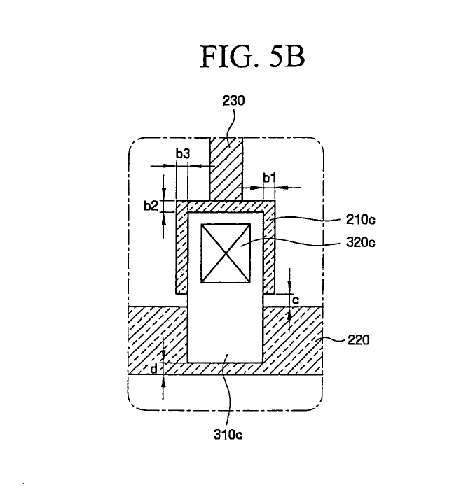

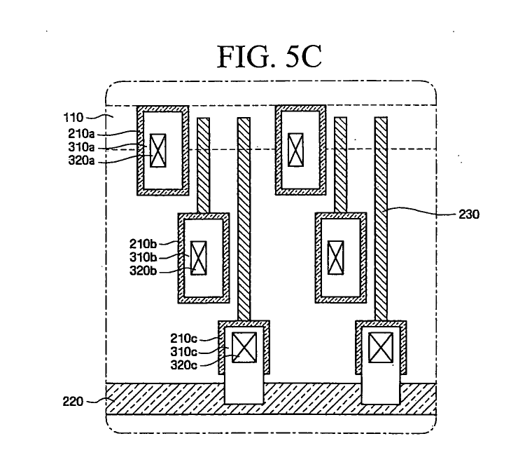

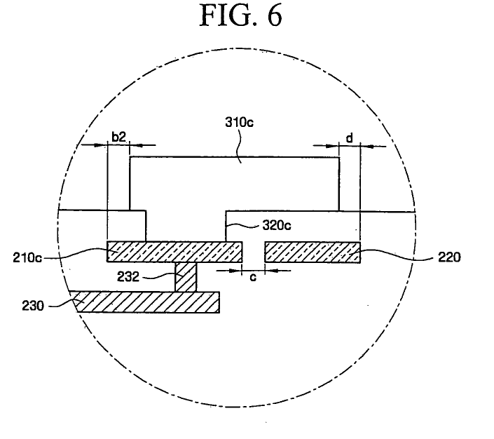

FIG. 3 is a layout view of a semiconductor integrated circuit device according to an example embodiment. FIG. 4 is a cross-sectional view of the semiconductor integrated circuit device taken along the lines A-A′ and B-B′ of FIG. 1. FIGS. 5A through 5C are enlarged views of regions C, D, and E shown in FIG. 3. FIG. 6 is an enlarged view of a region F shown in FIG. 4.

Referring to FIGS. 3 through 6, a semiconductor integrated circuit device 10 includes a substrate 101, a pair of ESD protection elements 110 formed in the substrate 101, first through third bumps 310a through 310c, and wiring structures 200a and 220c.

The substrate 101 may be made of at least one material selected from Si, Ge, SiGe, GaP, GaAs, SiC, SiGeC, InAs, InP, a combination thereof, or the like. The substrate 101 may be a P-type substrate or an N-type substrate. In addition, the substrate 101 may include a P well doped with P-type impurities or an N well doped with N-type impurities. The substrate 101 of the semiconductor integrated circuit device 10 according to at least this example embodiment may have a long axis and a short axis. Referring to FIG. 3, a direction of the long axis of the substrate 101 is defined herein as an X direction, and a direction of the short axis of the substrate 101 is defined herein as a Y direction.

The ESD protection elements 110 are formed in the substrate 101 and extend in a direction parallel to the direction of the long axis (the X direction) of the substrate 101. The ESD protection elements 110 are disposed adjacent to respective long edges of the substrate 101, which face each other. In this example, the ESD protection elements 110 may be disposed along respective long edges of the substrate 101 to be symmetrical to each other. The ESD protection elements 110 illustrated in FIG. 4 are of a transistor type. However, example embodiments are not limited to the transistor type, and all conventional types of ESD protection elements used in a semiconductor integrated circuit device in the semiconductor field may be used.

Still referring to FIG. 3, each of the ESD protection elements 110 is electrically connected to the first through third bumps 310a through 310c by wiring structures 200a and 200c. In this example, the wiring structures 200a and 200c are connected to impurity regions (hereinafter, referred to as “ESD impurity regions”) of each of the ESD protection elements 110. In FIG. 4, the wiring structures 200a and 200c are connected to N+-type impurity regions. However, example embodiments are not limited thereto. The ESD impurity regions connected to the wiring structures 200a and 200c may be N+-type impurity regions or P+-type impurity regions connected to the input/output pad I/O PAD illustrated in FIGS. 1B and 2B, for example.

In addition to the ESD protection elements 110, a plurality of integrated circuits and peripheral components are formed on the substrate 101 according to the design of a circuit to be implemented. An interlayer insulating film 130 is formed on the substrate 101 having the integrated circuits, and thus, covers the integrated circuits.

The first through third bumps 310a through 310c are formed on the interlayer insulating film 130. The first through third bumps 310a through 310c are input/output nodes connected to an input/output element of the semiconductor integrated circuit by first through third pads 210a through 210c formed under respective ones of the first through third bumps 310a through 310c. As discussed herein, the pads may also be referred to as wiring layers. The first through third bumps 310a through 310c are also connected to an external pad to exchange electrical signals with an external device. Furthermore, the first through third bumps 310a through 310c are electrically connected to each of the ESD protection elements 110; more specifically, to the ESD impurity regions.

The first through third bumps 310a through 310c are formed on the interlayer insulating film 130. In this example, a first bump group BG1 including the first bumps 310a is disposed in a first direction (the X-direction), a second bump group BG2 including second bumps 310b is disposed in the first direction, but separated from the first bump group in a second direction (the Y-direction). A third bump group BG3 including third bumps 310c are also arranged in the first direction, but separated from the second and third groups of bumps in the second direction. In addition, each third bump 310c in the third bump group BG3 is offset from a corresponding first and second bump 310a and 310b in the first direction.

Referring to FIG. 3, the semiconductor integrated circuit device 10 according to at least this example embodiment includes at least three rows of bump groups formed adjacent to a long edge of the semiconductor integrated circuit device 10. The semiconductor integrated circuit 10 further includes at least three additional rows of bump groups, which are symmetrical to the above at least three rows of bump groups formed adjacent to the other long edge of the semiconductor integrated circuit device 10. Although only six rows of bump groups are illustrated in FIG. 3, example embodiments are not limited to six rows. It is obvious that more or less than six rows of bump groups may be formed.

The first through third pads 210a through 210c are formed under respective ones of the first through third bumps 310a through 310c and are electrically connected to respective ones of the first through third bumps 310a through 310c. The first through third pads 210a through 210c deliver an input/output signal into each of the ESD protection elements 110. The first through third bumps 310a through 310c are electrically connected to the first through third pads 210a through 210c by contacts 320a through 320c, respectively. The first through third pads 210a through 210c may have at least an edge overlapped the contacts 320a through 320c or aligned a sidewall of the contacts 320a through 320c, respectively. The first through third pads 210a through 210c are disposed under respective ones of the first through third bumps 310a through 310c, and at least part of each of the first through third pads 210a through 210c is overlapped by a corresponding one of the first through third bumps 310a through 310c. In other words, the first through third pads 210a through 210c is partially or completely overlapped by a corresponding one of the first through third bumps 310a through 310c.

More specifically, referring to FIGS. 3 through 5A and 5C, the first pad 210a formed under each of the first bumps 310a may be larger than each of the first bumps 310a. In this case, the four edges of the first pad 210a extend beyond the four edges of a corresponding one of the first bumps 310a to enhance contact between each of the first bumps 310a and an external pad by making a top surface of each of the first bumps 310a as flat as possible. In this example, distances a1 through a4 (shown in FIG. 5A), by which the four edges of each of the first bumps 310a are separated from the four edges of the first pad 210a, may be adjusted without affecting the flatness of the top surface of each of the first bumps 310a. In this example, the distances a1 through a4 may be less than or equal to approximately 10 μm.

Alternatively, the size of the first pad 210a may be reduced such that the four edges of the first pad 210a are within the four edges of each of the first bumps 310a. In this case, a region under each of the first bumps 310a may be divided into a region in which the first pad 210a is formed and a region in which the first pad 210a is not formed. Accordingly, a step height may be created between the region in which the first pad 210a is formed and the region in which the first pad 210a is not formed. The step height may affect (e.g., reduce) the flatness of the top surface of each of the first bumps 310a.

Each of the first bumps 310a is connected to an external input/output terminal, and thus, delivers an input/output signal. The operation of the semiconductor integrated circuit device 10 depends (e.g., greatly depends) on whether each of the first bumps 310a contacts the external input/output terminal normally. Thus, each of the first bumps 310a contacts the external input/output terminal in a relatively stable manner. For this reason, the top surface of each of the first bumps 310a may be as flat as possible, so that the surface may contact and be adhered to the external input/output terminal in a relatively stable manner.

In the semiconductor integrated circuit device 10 according to at least this example embodiment, the four edges of the first pad 210a formed under each of the first bumps 310a extend beyond the four edges of each of the first bumps 310a. Thus, the flatness of the top surface of each of the first bumps 310 may be improved, which in turn, may enhance the stability of the semiconductor integrated circuit device 10.

The first pad 210a is connected to each of the ESD protection elements 110 and/or the input/output element. For example, as illustrated in FIG. 4, the first pad 210a is connected to each of the ESD protection elements 110; more specifically, an ESD impurity region, by the wiring structure 200a. The wiring structure 200a is formed by alternately stacking a plurality of wiring layers and a plurality of vias within the interlayer insulating film 130.

The above description may also apply to the second bumps 310b and the second pad 210b. For example, the four edges of the second pad 210b extend beyond the four edges of each of the second bumps 310b. In addition, the second pad 210b is connected to each of the ESD protection elements 110 and/or the input/output terminal. In this example, the second pad 210b is connected to each of the ESD protection elements 110; more specifically, an ESD impurity region, by a wiring structure (not shown), which is formed by alternately stacking a plurality of wiring layers and a plurality of vias within the interlayer insulating film 130.

Referring to FIGS. 3, 4, 5B, 5C, and 6, the third pad 210c formed under each of the third bumps 310c is overlapped by part of each of the third bumps 310c to form upper wiring 220, which will be described later, under each of the third bumps 310c. Generally, a plurality of bumps formed in a single integrated circuit device have the same or similar size. The fact that the third pad 210c formed under each of the third bumps 310c is overlapped by part of each of the third bumps 310c indicates that the third pad 210c is smaller than the first pad 210a and the second pad 210b, although this may not always be the case.

The third pad 210c may be formed under each of the third bumps 310c at a location closer to each of the ESD protection elements 110 because the third pad 210c is electrically connected to each of the ESD protection elements 110. In addition, three edges of a top surface of the third pad 210c excluding an edge, which is overlapped by part of each of the third bumps 310c, extend beyond each of the third bumps 310c. In this example, distances b1 through b3 by which the three edges of the third pad 210c are separated from each of the third bumps 310c may be the same or similar to the distances a1 through a4 by which the edges of the first pad 210a are separated from each of the first bumps 310a. For example, the distances b1 through b3 may be less than or equal to approximately 10 μm.

The third pad 210c is electrically connected to each of the ESD protection elements 110 and/or the input/output terminal. For example, as illustrated in FIG. 4, the third pad 210c is connected to each of the ESD protection elements 110; more specifically, an ESD impurity region, by the wiring structure 200c. The wiring structure 200c is formed by alternately stacking a plurality of wiring layers and a plurality of vias within the interlayer insulating film 130.

Referring to FIGS. 3, 4 and 6, the third pad 210c is separated from each of the ESD protection elements 110 in a horizontal direction, more specifically, in the direction of the short axis (the Y direction) of the substrate 101. To electrically connect the third pad 210c and each of the ESD protection elements 110, the third pad 210c is connected to a first via 232 (see FIG. 6), and an intermediate wiring layer 230 connected to the first via 232 extends toward each of the ESD protection elements 110. The intermediate wiring layer 230 is connected to the wiring structure 200c formed on each of the ESD protection elements 110, and thus, electrically connects each of the ESD protection elements 110 to the third bumps 310. For example, the intermediate wiring layer 230 may extend from each of the ESD protection elements 110 up to under the third pad 210c in the direction of the short axis (the Y direction) of the substrate 101. The intermediate wiring layer 230 may be formed on a layer different from a layer on which the third pad 210c is formed. For example, the intermediate wiring layer 230 may be formed on a layer lower than a layer on which the third pad 210c is formed. Meanwhile, the wiring structure 200a or 200c is disposed below one of the first through third bumps 310a through 310c. Also, the ESD impurity region is disposed below one of the first through third bumps 310a through 310c.

The upper wiring 220 may extend, for example, in the direction of the long axis (the X direction) of the substrate 101 and may be the same or substantially the same as a direction in which the ESD protection elements 110 extend and/or a direction in which the third bumps 310c are arranged. Accordingly, the upper wiring 220 is formed under the third bumps 310c, and part of the upper wiring 220 is overlapped by each of the third bumps 310c. In addition, the upper wiring 220 is separated from the third pad 210c at the same or substantially the same level as the third pad 210c and extends in one direction. The interlayer insulating film 130 is interposed between the third bumps 310c and the upper wiring 220 to insulate the third bumps 310c from the upper wiring 220.

The upper wiring 220 is separated from the third pad 210c by a given, desired or predetermined distance, and is formed at the same or substantially the same level as the third pad 210c. The third bumps 310c may have a short axis and a long axis. The direction in which the third bumps 310c are arranged may be the same or substantially the same as a direction of the short axis of the third bumps 310c. The third pad 210c and the upper wiring 220 may be separated from each other in the direction of the long axis of the third bumps 310c. In this case, a distance “c” (shown in FIGS. 5B and 6) between the third pad 210c and the upper wiring 220 may be less than or equal to about 4 μm.

As noted above, the upper wiring 220 extends under the third bumps 310c. In addition, part of the upper wiring 220 is overlapped by each of the third bumps 310c. In this example, an edge of the upper wiring 220 is not overlapped by each of the third bumps 310c, but rather extends beyond each of the third bumps 310c. Referring to the example embodiment shown in FIG. 5B, an edge of the upper wiring 220 is separated from each of the third bumps 310c by a distance “d.”

The relationship between the third bumps 310c, the third pad 210c, and the upper wiring 220 of the semiconductor integrated circuit device 10 according to at least this example embodiment will now be described in more detail with reference to FIGS. 5B and 6.

Referring to FIGS. 5B and 6, the third pad 210c and the upper wiring 220 are formed under each of the third bumps 310c to be overlapped by each of the third bumps 310c. The third pad 210c is electrically connected to each of the third bumps 310c, and thus, connected to each of the ESD protection elements 110 and/or the input/output element. The third pad 310c corresponds to the first pad 210a formed under each of the first bumps 310a and the second pad 210b formed under each of the second bumps 310b. The upper wiring 220 is insulated from the third bumps 310c and may be used for routing.

For example, the upper wiring 220 formed under the third bumps 310c and at the same or substantially the same level as the third pad 210c may be used as additional wiring for routing. In addition, because the upper wiring 220 is formed at the same or substantially the same level as the third pad 210c and part of the upper wiring 220 is overlapped by each of the third bumps 310c, space in the semiconductor integrated circuit device 10 may be utilized more efficiently. As a result, the integration density of the semiconductor integrated circuit device 10 may be increased.

As semiconductor integrated circuit devices become smaller, the size of semiconductor chips decreases, and the area of a semiconductor chip occupied by bumps increases. For example, when there are hundreds or thousands of input/output terminals as in display drive integrated circuit (DDI) chips, bumps occupy a relatively large area of a semiconductor chip. Therefore, if a region under the third bumps 310c is utilized efficiently by forming wiring as in the semiconductor integrated circuit device 10 according to at least this example embodiment, the integration density of the semiconductor integrated circuit device 10 may be increased.

For example, when a short axis is shorter (e.g., much shorter) than a long axis as in DDI chips, the area of the short axis may be utilized more efficiently, thereby improving integration density. When a length of the semiconductor integrated circuit device 10 in the direction of the long-axis (the X direction) is shorter (e.g., far shorter) than a length of the semiconductor integrated circuit device 10 in the direction of the short axis (the Y direction) as illustrated in FIG. 3, the integration density of the semiconductor integrated circuit device 10 in the direction of the short axis (the Y direction) may be increased to further reduce the length of the semiconductor integrated circuit device 10 in the direction of the short axis (the Y direction).

A top surface of each bump may be formed as flat as possible for better adherence to an external pad. However, when two or more patterns are formed under a bump, the flatness of a top surface of the bump may be undermined by the patterns formed under the bump. This is because the flatness of the top surface of the bump may be affected by the evenness of the patterns. The flatness of the top surface of the bump varies according to a gap between the two patterns formed under the bump. Therefore, the gap between the two patterns must be adjusted such that the top surface of the bump is as flat as possible. For example, the two patterns may be separated from each other by a gap, which improves the flatness of the top surface of the bump while insulating the two patterns from each other.

In the semiconductor integrated circuit device 10 according to at least this example embodiment, the distance “c” between the two patterns (e.g., the third pad 210c and the upper wiring 220) formed under each of the third bumps 310c is adjusted to less than or equal to about 4 μm, so that the top surface of each of the third bumps 310c maintains a given, desired or predetermined degree of flatness. According to experimental results described in more detail later, when the distance “c” between the two patterns formed under each of the third bumps 310c is less than or equal to about 4 μm, the flatness of each of the third bumps 310c is improved.

In the semiconductor integrated circuit device 10 according to at least this example embodiment, edges of the third pad 210c formed under each of the third bumps 310c and an edge of the upper wiring 220 formed under the third bumps 310c may extend beyond each of the third bumps 310c, excluding an edge of the third pad 210c and an edge of the upper wiring 220, which are adjacent to each other. For example, three edges of the third pad 210c may be separated from each of the third bumps 310c by the distances b1 through b3, and an edge of the upper wiring 220 may be separated from the third bumps 310c by the distance “d.” Therefore, little or no step height is created in the region under the third bumps 310c, except for the distance “c.” As a result, the flatness of the top surface of each of the third bumps 310c is improved. In addition, because the distance “c” is maintained at less than or equal to about 4 μm to reduce (e.g., minimize) its effect on the flatness of the top surface of each of the third bumps 310c, the flatness of the top surface of each of the third bumps 310c may be improved. Thus, each of the third bumps 310c may contact an external terminal in a more stable manner.

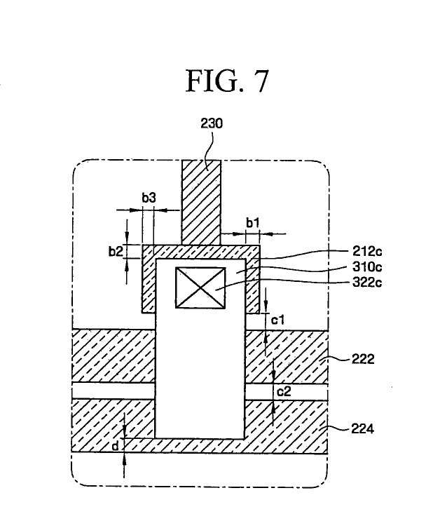

FIG. 7 is a diagram illustrating a semiconductor integrated circuit device according to another example embodiment. The semiconductor integrated circuit device according to at least this example embodiment is different from the semiconductor integrated circuit device 10 according to the above-described example embodiment in that a first upper wiring 222 and a second upper wiring 224 are formed under third bumps 310c.

Referring to FIG. 7, a third pad 212c, the first upper wiring 222, and the second upper wiring 224 are formed under each of the third bumps 310c. The third pad 212c is connected to each of the third bumps 310c by a third contact 322c. The first upper wiring 222 is formed at the same or substantially the same level as the third pad 212c and is separated from the third pad 212c by a distance “c1.” The second upper wiring 224 is formed at the same or substantially the same level as the first upper wiring 222 and is separated from the first upper wiring 222 by a distance “c2.” In this example, the distance “c1” and the distance “c2” may be less than or equal to about 4 μm.

In the semiconductor integrated circuit device according to at least this example embodiment, two routing wiring layers (e.g., the first upper wiring 222 and the second upper wiring 224) are formed under the third bumps 310c. Consequently, the integration density of the semiconductor integrated circuit device according to at least this example embodiment may be increased.

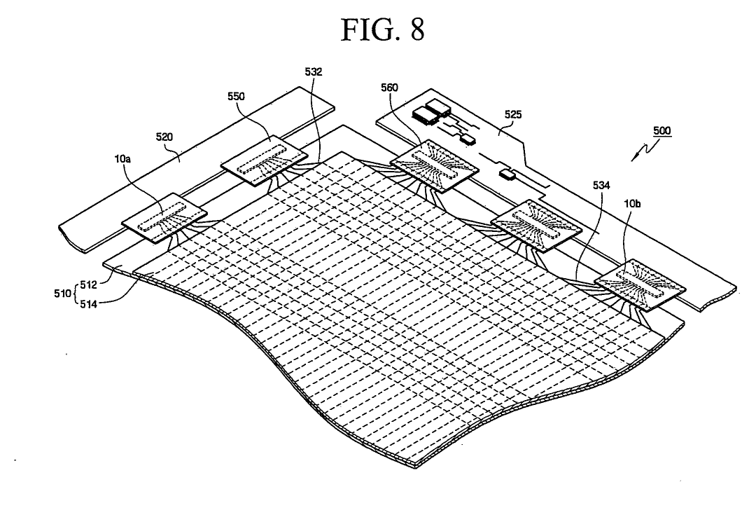

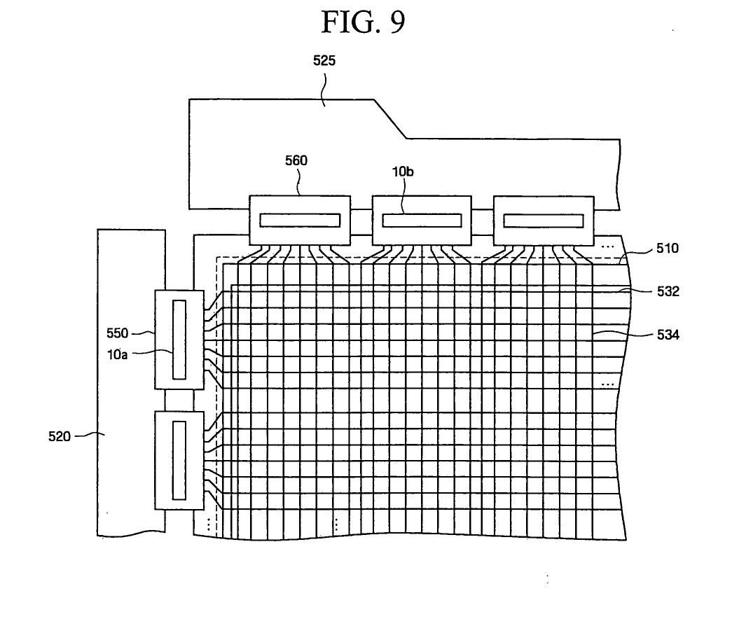

FIG. 8 is a partial perspective view of a liquid crystal panel assembly 500 included in a liquid crystal display (LCD) according to an example embodiment. FIG. 9 is a partial top view of the liquid crystal panel assembly 500 included in the LCD according to the example embodiment shown in FIG. 8.

Referring to FIGS. 8 and 9, the LCD according to at least this example embodiment includes the liquid crystal panel assembly 500. The liquid crystal panel assembly 500 includes a liquid crystal panel 510, first flexible films 550, second flexible films 560, a first printed circuit board (PCB) 520, and a second PCB 525.

The liquid crystal panel 510 includes a lower display panel 512 and an upper display panel 514, which is smaller than the lower display panel 512, and faces the lower display panel 512. The lower display panel 512 includes gate lines 532, data lines 534, thin-film transistors, pixel electrodes, and the like. The upper display panel 514 includes a black matrix, color filters, a common electrode, and the like. A liquid crystal layer (not shown) is interposed between the upper display panel 514 and the lower display panel 512.

Each of the first and second flexible films 550 and 560 may be a gate chip film package or a data chip film package. The gate or data chip film package may be, but not limited to, a tape carrier package (TCP) or a chip on film (COF) package.

The first flexible films 550 contact the lower display panel 512. Each of the first flexible films 550 includes the gate lines 532 formed on a base film and extending to the lower display panel 512, and a gate drive IC chip 10a formed on the base film. The gate drive IC chip 10a is a type of semiconductor chip and may be employed in a semiconductor integrated circuit device according to at least some example embodiments. The gate drive IC chip 10a and the gate lines 532 may be mounted on each of the first flexible films 550 using, for example, a tape automated bonding (TAB) method.

The second flexible films 560 contact the lower display panel 512. Each of the second flexible films 560 includes the data lines 534 formed on a base film and extending to the lower display panel 512, and a data drive IC chip 10b formed on the base film. The data drive IC chip 10b is a type of semiconductor chip and may be employed in a semiconductor integrated circuit device according to at least some example embodiments. The data drive IC chip 10b and the data lines 534 may be mounted on each of the second flexible films 560 using the TAB method.

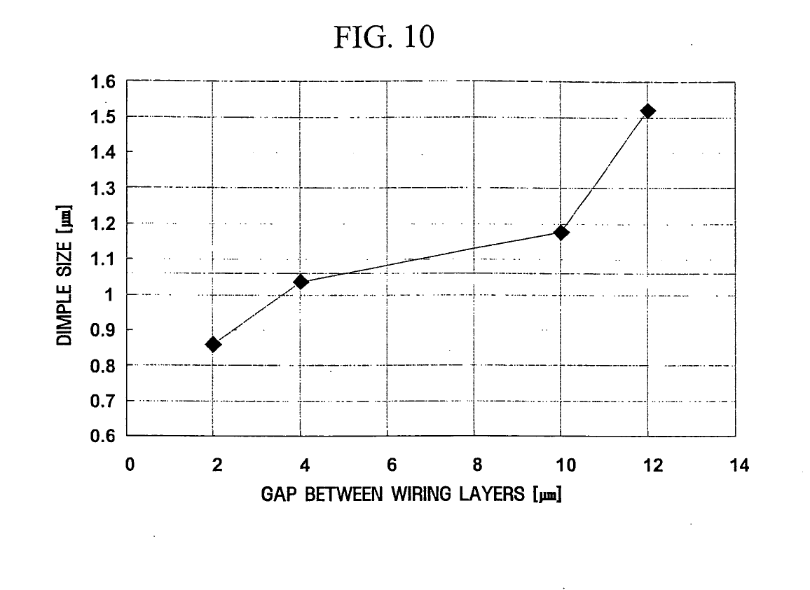

FIG. 10 is a graph illustrating example dimple size with respect to a gap between wiring layers.

The results illustrated in FIG. 10 were obtained by forming two or more wiring layers under a bump and measuring the size of a dimple in a top surface of the bump with respect to a gap between the wiring layers. In this example, the size of the dimple was measured by changing the gap between the wiring layers using a contact profiler, and the height of the bump used was approximately 1600 μm. The distance between a highest point and a lowest point in a region of the top surface of the bump, which corresponds to the gap between the wiring layers, was measured as the size of the dimple.

Referring to FIG. 10, as the gap between the wiring layers increases, the size of the dimple increases. For example, when the gap between the wiring layers is greater than or equal to about 5 μm, the size of the dimple is greater than or equal to about 1.1 μm.

Therefore, when the gap between the wiring layers formed under the bump is adjusted to less than or equal to about 4 μm, the size of the dimple formed in the top surface of the bump with a height of approximately 1600 μm may be adjusted to less than or equal approximately 1.1 μm.

While some example embodiments have been particularly shown and described, it will be understood by those of ordinary skill in the art that various changes in form and detail may be made therein without departing from the spirit and scope as defined by the following claims. The example embodiments should be considered in a descriptive sense only and not for purposes of limitation.

What is claimed is:

1. A semiconductor integrated circuit device comprising:
an electrostatic discharge (ESD) impurity region formed in a substrate;
a bump formed on the substrate; and
at least a first wiring layer and a second wiring layer formed at the same level under the bump, the first and second wiring layers being separated from each other and at least part of each of the first and second wiring layers being overlapped by the bump; wherein
the first wiring layer is electrically connected to the ESD impurity region and the bump, and
the second wiring layer is insulated from the bump.

2. The circuit device of claim 1, wherein the first wiring layer is closer to the ESD impurity region than the second wiring layer.

3. The circuit device of claim 1, wherein the bump has a long axis and a short axis, and the first wiring layer and the second wiring layer are separated from each other in a direction of the long axis of the bump.

4. The circuit device of claim 1, wherein each edge of each of the first wiring layer and the second wiring layer extends beyond the bump, excluding an edge of the first wiring layer and an edge of the second wiring layer, which are adjacent to each other.

5. The circuit device of claim 1, wherein the first wiring layer is separated from the second wiring layer by a gap of less than or equal to about 4 μm.

6. The circuit device of claim 1, further comprising:
an intermediate wiring layer extending from the ESD impurity region and electrically connecting the ESD impurity region to the first wiring layer.

7. The circuit device of claim 1, wherein a plurality of second wiring layers are formed and separated from each other.

8. The circuit device of claim 1, wherein a plurality of bumps arranged in a first direction, and the second wiring layer extends in the first direction such that at least part of the second wiring layer is overlapped by the bumps.

9. The circuit device of claim 1, wherein the bump is a first bump and the device further comprises:
a second bump and a third bump, which are separated from the first bump, wherein
the first bump, the second bump, and the third bump are sequentially arranged in a second direction, and
the third bump is formed adjacent to the ESD impurity region.

10. The circuit device of claim 9, further comprising:
a third wiring layer and a fourth wiring layer formed respectively under the second bump and the third bump, at least part of the third and fourth wiring layers being overlapped by the second bump and the third bump, respectively; wherein
the third wiring layer is electrically connected to the ESD impurity region and the second bump, and
the fourth wiring layer is electrically connected to the ESD impurity region and the third bump.

11. A semiconductor integrated circuit device comprising:
an ESD impurity region formed in a substrate;
a first bump group including a plurality of first bumps arranged on the substrate in the first direction;
a plurality of first pads formed respectively under the first bumps, at least part of each of the plurality of first pads being overlapped by a corresponding one of the first bumps, and each of the plurality of first pads being electrically connected to the ESD impurity region and the corresponding one of the first bumps; and
a first wiring layer formed at the same level as the first pads, the first wiring layer being separated from the first pads in a second direction, and the first wiring layer extending in the first direction such that part of the first wiring layer is overlapped by the first bumps.

12. The circuit device of claim 11, wherein the substrate has a long axis and a short axis, and wherein the first direction is a direction of the long axis of the substrate, and the second direction is a direction of the short axis of the substrate.

13. The circuit device of claim 12, further comprising:
at least one second bump group, each of the at least one second bump groups including a plurality of second bumps arranged on the substrate in the first direction; wherein
the at least one second bump groups and the first bump group are sequentially arranged in the second direction and are separated from each other.

14. The circuit device of claim 13, wherein the substrate is divided into a first region including a long edge of the substrate and a second region including the other long edge of the substrate, and wherein
the ESD impurity region, the first bump group, the at least one second bump groups, the first pads, and the first wiring layer are formed in the first region, and symmetric versions of the ESD impurity region, the first bump group, the at least one second bump groups, the first pads, and the first wiring layer formed in the first region are formed in the second region.

15. The circuit device of claim 13, wherein the at least one second bumps include a plurality of second bumps, the device further comprising:
a plurality of second pads formed respectively under the plurality of second bumps, at least part of each of the plurality of second pads being overlapped by a corresponding one of the plurality of second bumps, and electrically connected to the ESD impurity region and the corresponding one of the plurality of second bumps.

16. The circuit device of claim 15, wherein each edge of each of the plurality of second pads extend beyond the corresponding one of the plurality of second bumps.

17. The circuit device of claim 11, wherein the plurality of first pads are separated from the first wiring layer by a gap of less than or equal to about 4 μm.

18. The circuit device of claim 11, wherein the plurality of first pads are closer to the ESD impurity region than the first wiring layer, the circuit device further comprising:
a plurality of second wiring layers extending in the second direction to electrically connect each of the plurality of first pads to the ESD impurity region.
